(19) United States
(12) Patent Application Publication
(10) Pub. No.: US 2022/0293828 A1
(43) Pub. Date: Sep. 15, 2022

(54) ULTRAVIOLET LIGHT EMITTING DEVICE AND METHOD FOR PRODUCING SAME

(71) Applicant: TOYODA GOSEI CO., LTD., Kiyosu-shi (JP)

(72) Inventors: Shintaro HAKAMATA, Kiyosu-shi (JP); Shota Shimonishi, Kiyosu-shi (JP); Aya Kawaoka, Kiyosu-shi (JP); Takashi Shugo, Kiyosu-shi (JP); Takeshi Matsushima, Kiyosu-shi (JP); Kenichi Matsuura, Kiyosu-shi (JP); Kazuya Tachibana, Kiyosu-shi (JP); Takaaki Kamijo, Kiyosu-shi (JP)

(21) Appl. No.: 17/689,747

(22) Filed: Mar. 8, 2022

(30) Foreign Application Priority Data
Mar. 11, 2021 (JP) 2021-039374

(51) Int. Cl. H01L 33/50; H01L 33/56

(52) U.S. Cl. CPC H01L 33/502; H01L 33/56; H01L 2933/0041; H01L 2933/005

(57) ABSTRACT

In an ultraviolet light emitting device, a fluororesin layer includes an element covering portion that covers a second surface of an ultraviolet light emitting element, and a substrate covering portion that covers a mounting surface of a substrate. The substrate covering portion includes a flat portion having a flat surface. A distance from a point in the element covering portion farthest from the second surface of the ultraviolet light emitting element to the second surface of the ultraviolet light emitting element is 1.3 times or more and 5 times or less a distance from the flat surface of the flat portion of the substrate covering portion to the mounting surface of the substrate.

### CROSS-REFERENCE TO RELATED APPLICATIONS

The present application claims the benefit of priority of Japanese Patent Application No. 2021-039374, filed on Mar. 11, 2021, the disclosure of which is incorporated herein by reference.

### TECHNICAL FIELD

The technical field of the present specification relates to an ultraviolet light emitting device including an ultraviolet light emitting element and a method for producing the ultraviolet light emitting device.

### BACKGROUND ART

In a light emitting device that emits visible light, a semiconductor light emitting element mounted on a substrate is sealed with a resin. The sealing resin is, for example, a silicone resin or an epoxy resin. A refractive index of these resins is greater than a refractive index of the atmosphere. Therefore, reflection at an interface between the semiconductor light emitting element and the sealing resin is prevented. That is, light extraction efficiency is high.

In recent years, a light emitting device using an ultraviolet light emitting element has been researched and developed. For example, JP-A-2019-114741 discloses a light emitting device in which a coating film 5 such as glass is disposed on an ultraviolet light emitting element 2 and a sealing resin 4 such as a silicone resin is disposed on the coating film 5 (paragraphs [0020] to [0029] in JP-A-2019-114741).

### SUMMARY OF INVENTION

Ultraviolet light modifies the silicone resin and the epoxy resin. The resin cured or deteriorated by the ultraviolet light causes cracks. Therefore, an ultraviolet light emitting device that does not use a silicone resin or an epoxy resin has been developed.

However, it is not always easy to seal an ultraviolet light emitting element without using a resin suitable for sealing such as a silicone resin or an epoxy resin. In addition, when a silicone resin or the like is not used, the surface of the sealing member tends to be flat and the light extraction efficiency tends to decrease.

An object of the present specification is to provide an ultraviolet light emitting device in which an ultraviolet light emitting element is sealed and light extraction efficiency is improved.

An ultraviolet light emitting device according to a first aspect includes a substrate, an ultraviolet light emitting element, and a fluororesin layer. The substrate has a mounting surface. The ultraviolet light emitting element has a first surface having an electrode, a second surface opposite to the first surface, and a side surface. The electrode on the first surface of the ultraviolet light emitting element is bonded to the mounting surface of the substrate. The fluororesin layer includes an element covering portion that covers the second surface of the ultraviolet light emitting element, and a substrate covering portion that covers the mounting surface of the substrate. The substrate covering portion includes a flat portion having a flat surface located on a side opposite to the mounting surface. A distance from a point in the element covering portion farthest from the second surface of the ultraviolet light emitting element to the second surface of the ultraviolet light emitting element is 1.3 times or more and 5 times or less a distance from the flat surface of the flat portion of the substrate covering portion to the mounting surface of the substrate.

In the ultraviolet light emitting device, the fluororesin layer includes the element covering portion and the substrate covering portion. The element covering portion has a film thickness sufficiently larger than that of the substrate covering portion. Therefore, the light emitted from the second surface of the ultraviolet light emitting element is less likely to be reflected when the light goes out of the ultraviolet light emitting device. The light extraction efficiency of the ultraviolet light emitting device is high.

In the present specification, it is possible to provide an ultraviolet light emitting device in which an ultraviolet light emitting element is sealed and light extraction efficiency is improved.

### BRIEF DESCRIPTION OF DRAWINGS

FIG. 1 is a schematic configuration diagram of an ultraviolet light emitting device 100 according to a first embodiment.

FIG. 2 is a configuration diagram showing a shape of the ultraviolet light emitting device 100 according to the first embodiment.

FIG. 3 is a diagram (part 1) illustrating a method for producing the ultraviolet light emitting device 100 according to the first embodiment.

FIG. 4 is a diagram (part 2) illustrating the method for producing the ultraviolet light emitting device 100 according to the first embodiment.

FIG. 5 is a diagram (part 3) illustrating the method for producing the ultraviolet light emitting device 100 according to the first embodiment.

FIG. 6 is a diagram (part 4) illustrating the method for producing the ultraviolet light emitting device 100 according to the first embodiment.

FIG. 7 is a schematic configuration diagram of an ultraviolet light emitting device 200 according to a modification of the first embodiment.

FIG. 8 is a schematic configuration diagram of an ultraviolet light emitting device 300 according to a modification of the first embodiment.

FIG. 9 is a schematic configuration diagram of an ultraviolet light emitting device 400 according to a modification of the first embodiment.

### DESCRIPTION OF EMBODIMENTS

Hereinafter, specific embodiments will be described with reference to the drawings, taking an ultraviolet light emitting device and a method for producing the ultraviolet light emitting device as an example. However, the technique of the present specification is not limited to the embodiments. A structure different from that of the embodiment may be included. The thickness ratio of each layer in each figure is conceptually shown, and does not necessarily indicate the actual thickness ratio.

### (First Embodiment)

### 1. Ultraviolet Light Emitting Device

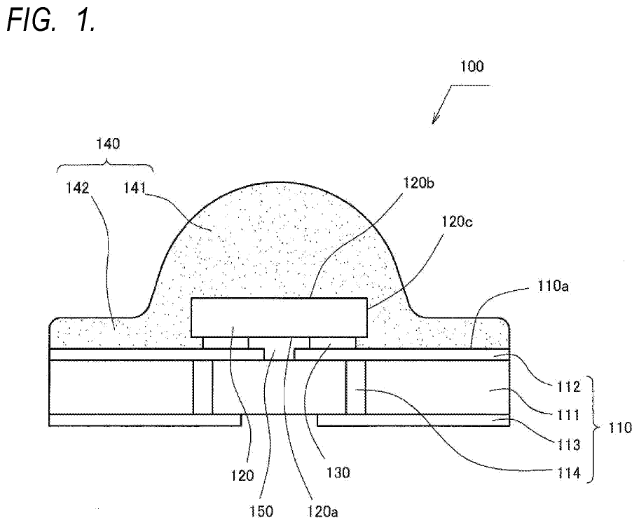

FIG. 1 is a schematic configuration diagram of an ultraviolet light emitting device 100 according to a first embodiment. As shown in FIG. 1, the ultraviolet light emitting device 100 includes a substrate 110, an ultraviolet light emitting element 120, a bonding layer 130, a fluororesin layer 140, and an air layer 150. The ultraviolet light emitting device 100 emits ultraviolet light.

The substrate 110 is a substrate for mounting the ultraviolet light emitting element 120. The substrate 110 has a mounting surface 110a. The mounting surface 110a is a surface for mounting the ultraviolet light emitting element 120. The substrate 110 includes a base material 111, circuit patterns 112 and 113, and a through hole 114. The circuit pattern 112 is a pattern on a mounting surface 110a side in the substrate 110. The circuit pattern 113 is a pattern on a side opposite to the mounting surface 110a side in the substrate 110. The through hole 114 electrically connects the circuit pattern 112 and the circuit pattern 113. The through hole 114 is filled with a metal. The mounting surface 110a is a surface of the circuit pattern 112.

The ultraviolet light emitting element 120 is a semiconductor light emitting element that emits ultraviolet light. An emission wavelength of the ultraviolet light emitting element 120 is, for example, 200 nm or more and 320 nm or less. The ultraviolet light emitting element 120 has a first surface 120a, a second surface 120b, and a side surface 120c. The first surface 120a has an electrode thereon. The first surface 120a faces the mounting surface 110a of the substrate 110. The electrode on the first surface 120a of the ultraviolet light emitting element 120 is bonded to the mounting surface 110a of the substrate 110 via the bonding layer 130. The second surface 120b is a surface opposite to the first surface 120a. The second surface 120b is a light extraction surface that extracts light to the outside of the ultraviolet light emitting element 120. The second surface 120b faces the fluororesin layer 140. The side surface 120c is a surface other than the first surface 120a and the second surface 120b.

The bonding layer 130 is a layer for mounting the ultraviolet light emitting element 120 on the substrate 110. The bonding layer 130 bonds the electrode on the first surface 120a of the ultraviolet light emitting element 120 and the circuit pattern 112 of the mounting surface 110a of the substrate 110. The material of the bonding layer 130 is, for example, an

Au-Sn solder.

The fluororesin layer 140 is made of a translucent fluororesin for suitably extracting ultraviolet light emitted from the ultraviolet light emitting element 120 to the outside. The fluororesin layer 140, of course, transmits ultraviolet light. The fluororesin layer 140 is fixed to the ultraviolet light emitting element 120 and the substrate 110.

The air layer 150 is a closed space located between the substrate 110 and the ultraviolet light emitting element 120. The air layer 150 is filled with a gas. The gas is, for example, atmosphere. The air layer 150 is located between the mounting surface 110a of the substrate 110 and the first surface 120a of the ultraviolet light emitting element 120. There is almost no air layer between the second surface 120b and the side surface 120c of the ultraviolet light emitting element 120 and the fluororesin layer 140.

### 2. Fluororesin Layer

### 2-1. Material of Fluororesin Layer

The material of the fluororesin layer 140 is fluororesin. The fluororesin is a polymer having a CF bond. The fluororesin is, for example, FEP. The fluororesin layer 140 has a refractive index higher than the refractive index of the atmosphere. The refractive index of the fluororesin layer 140 is, for example, 1.2 or more and 1.6 or less.

### 2-2. Region of Fluororesin Layer

As shown in FIG. 1, the fluororesin layer 140 includes an element covering portion »and a substrate covering portion 142.

The element covering portion 141 is a region occupying the vicinity of a center of the ultraviolet light emitting device 100. The element covering portion 141 covers the second surface 120b of the ultraviolet light emitting element 120. The element covering portion 141 is in contact with the second surface 120b of the ultraviolet light emitting element 120. The element covering portion 141 occupies a region above the second surface 120 b of the ultraviolet light emitting element 120. Since the second surface 120b of the ultraviolet light emitting element 120 is rectangular, a shape of a projection region after the element covering portion 141 is projected onto the substrate 110 is also rectangular.

The substrate covering portion 142 is a region occupying the vicinity of an outer edge of the ultraviolet light emitting device 100. The substrate covering portion 142 covers the mounting surface 110a of the substrate 110. The substrate covering portion 142 is in contact with the mounting surface 110a of the substrate 110. The substrate covering portion 142 occupies an outer region of the side surface 120c of the ultraviolet light emitting element 120. The substrate covering portion 142 is a region excluding the element covering portion 141. The substrate covering portion 142 surrounds around the element covering portion 141. The substrate covering portion 142 is a region close to an annular shape.

### 2-3. Shape of Fluororesin Layer

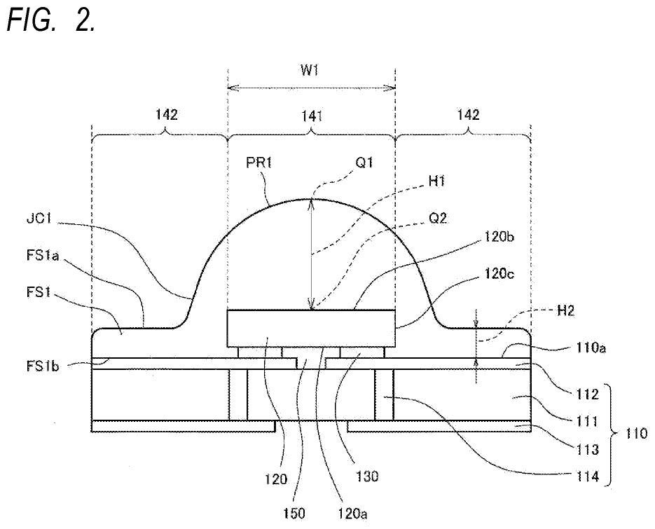

FIG. 2 is a configuration diagram showing a shape of the ultraviolet light emitting device 100 according to the first embodiment. As shown in FIG. 2, an extending surface of the side surface 120c of the ultraviolet light emitting element 120 is a boundary surface between the element covering portion 141 and the substrate covering portion 142.

The element covering portion 141 includes a convex portion PR1 in a direction away from the ultraviolet light emitting element 120. The convex portion PR1 has a dome shape.

A point Q1 is a point in the element covering portion 141 farthest from the second surface 120b of the ultraviolet light emitting element 120. A point Q2 is a point where the point Q1 is orthographically projected onto the second surface 120b of the ultraviolet light emitting element 120. The point Q2 is located near the center of the second surface 120b of the ultraviolet light emitting element 120. A distance H1 is a distance between the point Q1 and the point Q2. The distance H1 is a film thickness of the thickest portion of the element covering portion 141.

The substrate covering portion 142 includes a flat portion FS1 and a connecting portion JC1. The flat portion FS1 has a flat surface FS1a and a flat surface FS1b. The flat surface FS1a is a surface opposite to the mounting surface 110a of the substrate 110. The flat surface FS1b is a surface that is in contact with the mounting surface 110a of the substrate 110. A distance H2 is a distance between the flat surface FS1a and the flat surface FS1b. The distance H2 is a film thickness of the flat portion FS1.

The distance H1 is, for example, 200 pm or more and 500 pm or less. The distance H2 is, for example, 100 pm or more and 200 pm or less. A width W1 of the ultraviolet light emitting element 120, that is, a length of one side of the second surface 120b of the ultraviolet light emitting element 120 is, for example, 0.5 mm or more and 2 mm or less. A height of the ultraviolet light emitting element 120 is, for example, 0.3 mm or more and 0.7 mm or less.

The distance H1 from the point in the element covering portion 141 farthest from the second surface 120b of the ultraviolet light emitting element 120 to the second surface 120b of the ultraviolet light emitting element 120 is 1.3 times or more and 5 times or less the distance H2 from the flat surface FS1a of the flat portion FS1 of the substrate covering portion 142 to the mounting surface 110a of the substrate 110. That is, the distance H1 is 1.3 or more and 5 or less of the distance H2. Preferably, 1.4 or more and 4 or less. More preferably, 1.5 or more and 3 or less.

The distance H1 is, for example, 0.15 or more and 0.8 or less of the width W1. Preferably, 0.2 or more and 0.7 or less. More preferably, 0.2 or more and 0.6 or less.

The connecting portion JC1 is a region around the element covering portion 141.

The film thickness of the connecting portion JC1 becomes thicker toward the element covering portion 141. Therefore, the film thickness of the connecting portion JC1 is thicker than the film thickness of the flat portion FS1.

The fluororesin layer 140 does not fill a gap between the mounting surface 110a of the substrate 110 and the first surface 120a of the ultraviolet light emitting element 120. This unfilled gap is the air layer 150.

### 3. Refractive Index

The ultraviolet light emitting element 120 has a refractive index of about 1.7. The fluororesin layer 140 has a refractive index of 1.2 or more and 1.6 or less. The atmosphere has a refractive index of 1. The refractive index is higher in the order of the ultraviolet light emitting element 120, the fluororesin layer 140, and the atmosphere. In this case, total reflection is less likely to occur at the boundary between the materials.

In the first embodiment, the second surface 120b and the side surface 120c of the ultraviolet light emitting element 120 are not in contact with the air layer 150. As described above, the refractive index of the ultraviolet light emitting element 120 is sufficiently greater than the refractive index of the air layer 150. Since in the ultraviolet light emitting element 120, the second surface 120b and the side surface 120c from which the light is extracted to the outside are not in contact with the air layer 150 having a lower refractive index, the light from the ultraviolet light emitting element 120 is likely to be emitted to the outside of the element. Therefore, the light extraction efficiency of the ultraviolet light emitting device 100 is high.

### 4. Production Method

### 4-1. Element Mounting Step

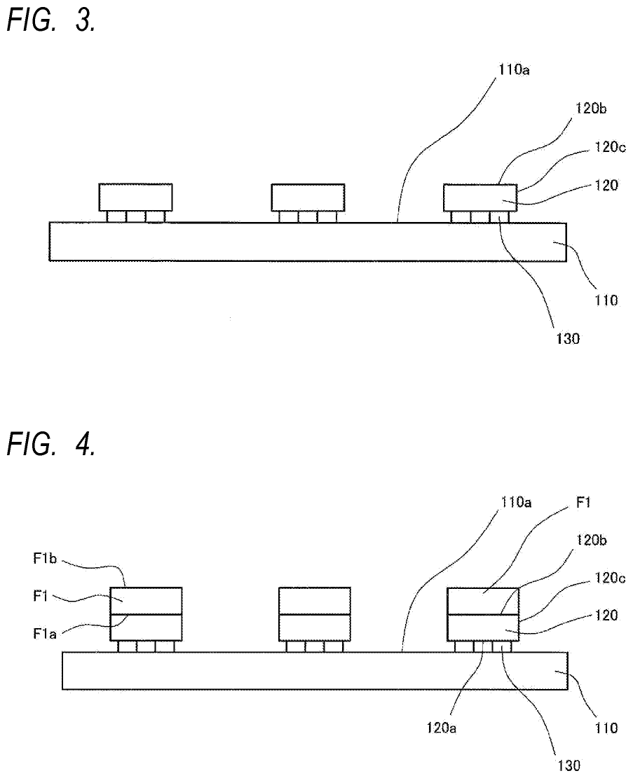

As shown in FIG. 3, the ultraviolet light emitting element 120 is mounted on the mounting surface 110a of the substrate 110. An Au-Sn solder is placed on the mounting surface 110a of the substrate 110. The ultraviolet light emitting element 120 is placed on the Au-Sn solder such that the electrode on the first surface 120a of the ultraviolet light emitting element 120 is in contact with the Au-Sn solder. Then, the ultraviolet light emitting element 120 is mounted on the substrate 110 by, for example, reflow. Accordingly, the first surface 120a of the ultraviolet light emitting element 120 is bonded to the mounting surface 110a of the substrate 110.

### 4-2. Fluororesin Piece Placement Step

As shown in FIG. 4, a fluororesin piece F1 is placed on the second surface 120b of the ultraviolet light emitting element 120. The fluororesin piece F1 is a fluororesin having a size same as that of the ultraviolet light emitting device 100. A width of the fluororesin piece F1 is about the same as the width W1 of the ultraviolet light emitting element 120. The fluororesin piece F1 is, for example, FEP. The fluororesin piece F1 has a first surface F1a and a second surface F1b. The second surface F1b is a surface opposite to the first surface F1a. The first surface F1a of the fluororesin piece F1 is in contact with the second surface 120b of the ultraviolet light emitting element 120. The number of the fluororesin piece F1 is the same as the number of the ultraviolet light emitting element 120. That is, the fluororesin piece F1 is disposed on each ultraviolet light emitting element 120.

4-3. Fluororesin Sheet Placement Step

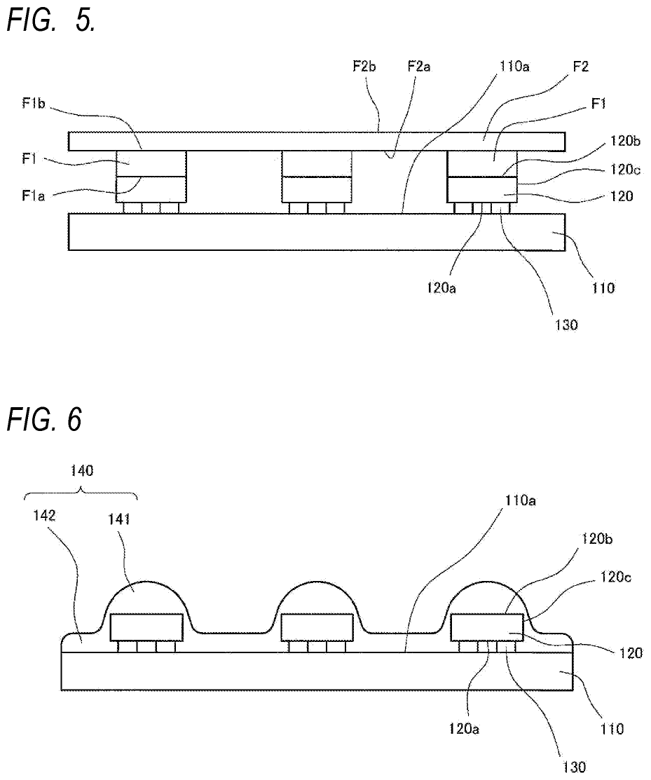

As shown in FIG. 5, a fluororesin sheet F2 is placed on the fluororesin piece F1. The material of the fluororesin piece F1 is the same as the material of the fluororesin sheet F2. A film thickness of the fluororesin sheet F2 is smaller than a film thickness of the fluororesin piece F1. The fluororesin sheet F2 has a first surface F2a and a second surface F2b. The second surface F2b is a surface opposite to the first surface F2a. The first surface F2a of the fluororesin sheet F2 is in contact with the second surface F1b of the fluororesin piece F1. Nothing is disposed on the second surface F2b of the fluororesin sheet F2.

### 4-4. Pressure Reduction Step

Next, the laminate in the state shown in FIG. 5 is placed in a vacuum heating device.

Then, the pressure in the vacuum heating device is reduced. The internal pressure of the vacuum heating device is, for example, 1 Pa or more and 100 Pa or less.

### 4-5. Reduced-pressure Heating Step

Next, the laminate is heated under the above reduced pressure state. The heating temperature is, for example, 100° C. or higher and 500° C. or lower. The heating temperature may be adjusted according to melting points of the fluororesin piece F1 and the fluororesin sheet F2. Accordingly, the fluororesin piece F1 and the fluororesin sheet F2 are melted almost at the same time (see FIG. 6). In this way, when the fluororesin sheet F2 is melted, the fluororesin piece F1 is melted and the fluororesin piece F1 and the fluororesin sheet F2 are fused with each other. The holding time is, for example, 1 minute or longer and 10 minutes or shorter.

### 4-6. Pressure Restoration Step

As shown in FIG. 6, the element covering portion 141 is formed on the second surface 120b of the ultraviolet light emitting element 120, and the substrate covering portion 142 is formed on the mounting surface 110a of the substrate 110. Therefore, the inside of the vacuum heating device is restored to atmospheric pressure while maintaining the heating temperature. From the reduced-pressure heating step to the pressure restoration step, the fluororesin piece F1 and the fluororesin sheet F2 are fixed to the ultraviolet light emitting element 120 and the substrate 110.

### 4-7. Leaving Step

The laminate is left in the vacuum heating device for a while. Accordingly, the inside of the vacuum heating device is lowered to room temperature. Alternatively, the inside of the vacuum heating device may be cooled to room temperature.

### 4-8. Other Steps

The substrate 110 is cut out for each ultraviolet light emitting device 100. Other steps may be performed.

### 5. Effects of First Embodiment

The fluororesin layer 140 of the ultraviolet light emitting device 100 according to the first embodiment includes the element covering portion 141 and the substrate covering portion 142. The element covering portion 141 includes the convex portion PR1 protruding from the second surface 120b of the ultraviolet light emitting element 120. The convex portion PR1 is sufficiently high and has a curved surface that is significantly different from the flat surface. Therefore, the light incident on the fluororesin layer 140 from the second surface 120b of the ultraviolet light emitting element 120 is less likely to be reflected when the light goes out of the ultraviolet light emitting device 100 from the convex portion PR1. That is, the light extraction efficiency of the ultraviolet light emitting device 100 is high.

### 6. Modifications

### 6-1. Fluororesin Layer (Part 1)

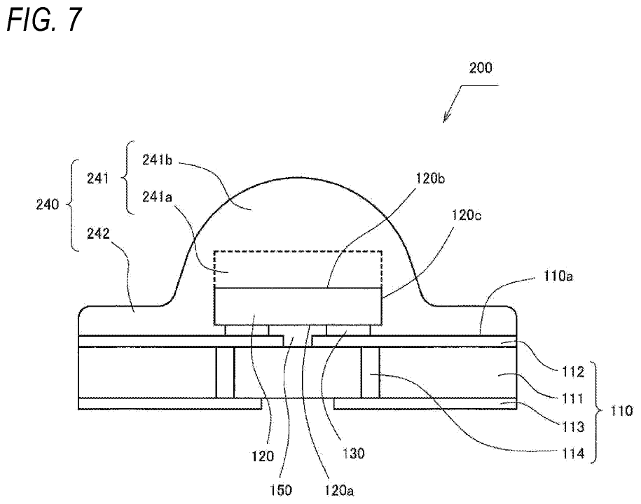

FIG. 7 is a schematic configuration diagram of an ultraviolet light emitting device 200 according to a modification of the first embodiment. As shown in FIG. 7, the ultraviolet light emitting device 200 includes the substrate 110, the ultraviolet light emitting element 120, the bonding layer 130, and a fluororesin layer 240. The fluororesin layer 240 includes an element covering portion 241 and a substrate covering portion 242. The element covering portion 241 has a first layer 241 a and a second layer 241b. The first layer 241a is a layer derived from the fluororesin piece F1. The second layer 241b is a layer derived from the fluororesin sheet F2. The fluororesin piece F1 and the fluororesin sheet F2 are made of different fluororesins. The melting point of the fluororesin piece F1 is higher than the melting point of the fluororesin sheet F2. Therefore, the fluororesin piece F1 does not melt inside the vacuum heating device and remains as the first layer 241a. That is, the first layer 241a and the second layer 241b are not fused with each other. The first layer 241a covers the second surface 120b of the ultraviolet light emitting element 120. The second layer 241b covers the side surface 120c of the ultraviolet light emitting element 120 and the first layer 241a.

### 6-2. Fluororesin Layer (Part 2)

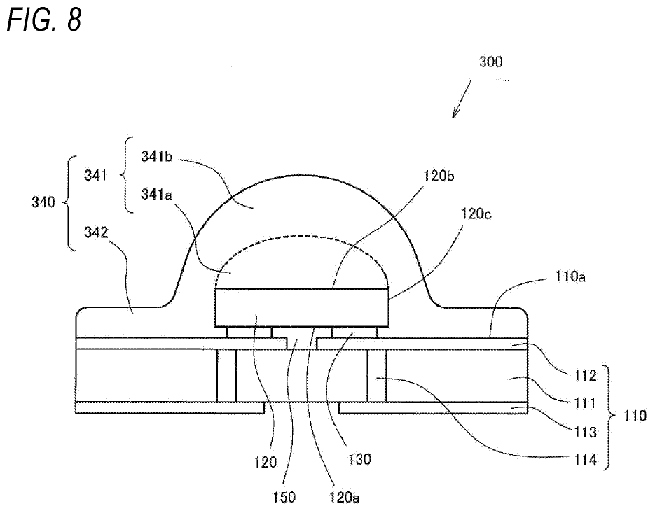

FIG. 8 is a schematic configuration diagram of an ultraviolet light emitting device 300 according to a modification of the first embodiment. As shown in FIG. 8, the ultraviolet light emitting device 300 includes the substrate 110, the ultraviolet light emitting element 120, the bonding layer 130, and a fluororesin layer 340. The fluororesin layer 340 includes an element covering portion 341 and a substrate covering portion 342. The element covering portion 341 has a first layer 341a and a second layer 341b. The first layer 341a is a layer derived from the fluororesin piece F1. The second layer 341b is a layer derived from the fluororesin sheet F2. The fluororesin piece F1 and the fluororesin sheet F2 are made of different fluororesins. Inside the vacuum heating device, the fluororesin piece F1 and the fluororesin sheet F2 are melted. Then, the fluororesin piece F1 becomes the dome-shaped first layer 341a, and the fluororesin sheet F2 becomes the second layer 341b that covers the first layer 341a. The first layer 341a and the second layer 341b are fused with each other. Here, it is preferable that the refractive index of the first layer 341a is larger than the refractive index of the second layer 341b.

### 6-3. Fluororesin Layer (Part 3)

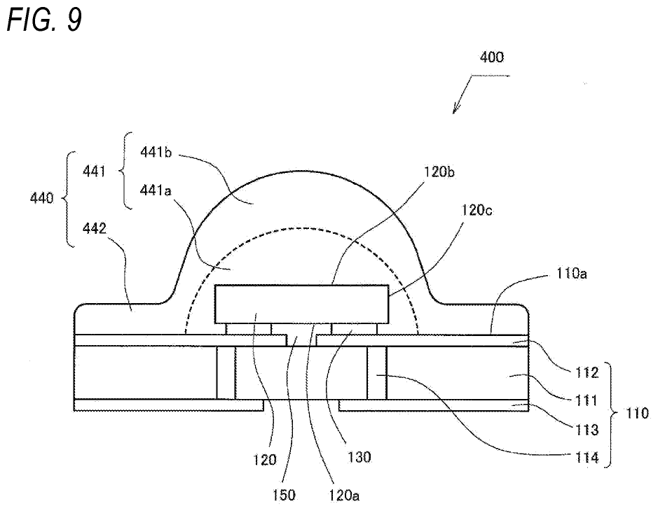

FIG. 9 is a schematic configuration diagram of an ultraviolet light emitting device 400 according to a modification of the first embodiment. As shown in FIG. 9, the ultraviolet light emitting device 400 includes the substrate 110, the ultraviolet light emitting element 120, the bonding layer 130, and a fluororesin layer 440. The fluororesin layer 440 includes an element covering portion 441 and a substrate covering portion 442. The element covering portion 441 has a first layer 441a and a second layer 441b. The first layer 441a is a layer derived from the fluororesin piece F1. The second layer 441b is a layer derived from the fluororesin sheet F2. The fluororesin piece F1 and the fluororesin sheet F2 are made of different fluororesins. The second layer 441b covers the side surface 120c of the ultraviolet light emitting element 120. Here, the width of the fluororesin piece Fl is larger than the width W1 of the ultraviolet light emitting element 120. Therefore, when the fluororesin piece Fl melts, the fluororesin piece Fl covers the side surface 120c of the ultraviolet light emitting element 120.

### 6-4. Material

The material of the fluororesin layer 140 is, for example, FEP, PFA, PTFE, ETFE, PVDF, PCTFE, and ECTFE.

### 6-5. Film Thickness of Fluororesin Sheet

The film thickness of the fluororesin sheet F2 may be larger than the film thickness of the fluororesin piece F1.

### 6-6. Air Layer

The air layer 150 may be filled with an underfill.

### 6-7. Combination

The above modifications may be freely combined.

### (Evaluation Test)

### 1. Preparation of Sample

Three types of samples were prepared. Sample 1 was a light emitting device in which the ultraviolet light emitting element 120 was simply mounted on the substrate 110. Sample 2 was a light emitting device in which the ultraviolet light emitting element 120 was covered with a fluororesin sheet of FEP on the sample 1. Sample 3 was a light emitting device in which a fluororesin piece F1 of FEP was placed on the sample 1, and a fluororesin sheet F2 of FEP was placed thereon and melted. In the sample 3, the fluororesin layer directly above the ultraviolet light emitting element 120 is raised in a lens shape.

### 2. Test Results

Table 1 is a table showing the test results. The brightness is standardized by the brightness of the sample 1. As shown in Table 1, the sample 3 corresponding to the ultraviolet light emitting device 100 according to the first embodiment is about 20% brighter than the sample 1 without the fluororesin sheet. The sample 3 is about 10% brighter than the sample 2.

TABLE 1

| Sample | Brightness |
|---|---|
| Sample 1 | 1 |
| Sample 2 | 1.1 |
| Sample 3 | 1.2 |

### (Appendix)

An ultraviolet light emitting device according to a first aspect includes a substrate, an ultraviolet light emitting element, and a fluororesin layer. The substrate has a mounting surface. The ultraviolet light emitting element has a first surface having an electrode, a second surface opposite to the first surface, and a side surface. The electrode on the first surface of the ultraviolet light emitting element is bonded to the mounting surface of the substrate. The fluororesin layer includes an element covering portion that covers the second surface of the ultraviolet light emitting element, and a substrate covering portion that covers the mounting surface of the substrate. The substrate covering portion includes a flat portion having a flat surface located on a side opposite to the mounting surface. A distance from a point in the element covering portion farthest from the second surface of the ultraviolet light emitting element to the second surface of the ultraviolet light emitting element is 1.3 times or more and 5 times or less a distance from the flat surface of the flat portion of the substrate covering portion to the mounting surface of the substrate.

In an ultraviolet light emitting device according to a second aspect, the element covering portion has a first layer that covers the second surface of the ultraviolet light emitting element and a second layer that covers the first layer. The first layer and the second layer are made of fluororesins.

In an ultraviolet light emitting device according to a third aspect, the first layer and the second layer are fused with each other.

In an ultraviolet light emitting device according to a fourth aspect, the first layer and the second layer are not fused with each other.

A method for producing an ultraviolet light emitting device according to a fifth aspect includes: placing a fluororesin piece on a second surface of an ultraviolet light emitting element having a first surface mounted on a substrate; placing a fluororesin sheet on the fluororesin piece; melting the fluororesin sheet by heating under a reduced pressure; and fixing the fluororesin sheet is fixed to the ultraviolet light emitting element and the substrate.

In a method for producing an ultraviolet light emitting device according to a sixth aspect, the fluororesin piece and the fluororesin sheet are made of the same material. When the fluororesin sheet is melted, the fluororesin piece is melted and the fluororesin piece and the fluororesin sheet are fused with each other.

In a method for producing an ultraviolet light emitting device according to a seventh aspect, the fluororesin piece and the fluororesin sheet are made of different materials. When the fluororesin sheet is melted, the fluororesin piece does not melt.

In a method for producing an ultraviolet light emitting device according to an eighth aspect, the fluororesin piece and the fluororesin sheet are made of different materials. When the fluororesin sheet is melted, the fluororesin piece is melted and the fluororesin piece and the fluororesin sheet are fused with each other.

What is claimed is:

1. An ultraviolet light emitting device comprising:
a substrate;
an ultraviolet light emitting element; and
a fluororesin layer, wherein
the substrate has a mounting surface,
the ultraviolet light emitting element has a first surface having an electrode, a second surface opposite to the first surface, and a side surface,
the electrode on the first surface of the ultraviolet light emitting element is bonded to the mounting surface of the substrate,
the fluororesin layer includes an element covering portion that covers the second surface of the ultraviolet light emitting element, and a substrate covering portion that covers the mounting surface of the substrate,
the substrate covering portion includes a flat portion having a flat surface located on a side opposite to the mounting surface, and
a distance from a point in the element covering portion farthest from the second surface of the ultraviolet light emitting element to the second surface of the ultraviolet light emitting element is 1.3 times or more and 5 times or less a distance from the flat surface of the flat portion of the substrate covering portion to the mounting surface of the substrate.

2. The ultraviolet light emitting device according to claim 1, wherein the element covering portion has a first layer that covers the second surface of the ultraviolet light emitting element, and a second layer that covers the first layer, and the first layer and the second layer are made of fluororesins.

3. The ultraviolet light emitting device according to claim 2, wherein the first layer and the second layer are fused with each other.

4. The ultraviolet light emitting device according to claim 2, wherein the first layer and the second layer are not fused with each other.

5. A method for producing an ultraviolet light emitting device comprising:
placing a fluororesin piece on a second surface of an ultraviolet light emitting element having a first surface mounted on a substrate;
placing a fluororesin sheet on the fluororesin piece;
melting the fluororesin sheet by heating under a reduced pressure; and
fixing the fluororesin sheet is fixed to the ultraviolet light emitting element and the substrate.

6. The method for producing an ultraviolet light emitting device according to claim 5, wherein
the fluororesin piece and the fluororesin sheet are made of the same material, and
when the fluororesin sheet is melted, the fluororesin piece is melted and the fluororesin piece and the fluororesin sheet are fused to each other.

7. The method for producing an ultraviolet light emitting device according to claim 5, wherein
the fluororesin piece and the fluororesin sheet are made of different materials, and
when the fluororesin sheet is melted, the fluororesin piece does not melt.

8. The method for producing an ultraviolet light emitting device according to claim 5, wherein
the fluororesin piece and the fluororesin sheet are made of different materials, and
when the fluororesin sheet is melted, the fluororesin piece is melted and the fluororesin piece and the fluororesin sheet are fused to each other.
